(19) United States
(12) Patent Application Publication
(10) Pub. No.: US 2024/0058922 A1
(43) Pub. Date: Feb. 22, 2024

(54) WORKPIECE PROCESSING METHOD

(71) Applicant: DISCO CORPORATION, Tokyo (JP)

(72) Inventors: Minoru MATSUZAWA, Tokyo (JP); Kohei TSUJIMOTO, Tokyo (JP); Yusuke FUJII, Tokyo (JP)

(21) Appl. No.: 18/363,939

(22) Filed: Aug. 2, 2023

(30) Foreign Application Priority Data
Aug. 22, 2022 (JP) 2022-132033

(51) Int. Cl. B24B 37/04; B24B 37/10; B24B 57/02

(52) U.S. Cl. CPC B24B 37/042; B24B 37/10; B24B 57/02

(57) ABSTRACT

Pressing a protective member causes the protective member to be embedded in boundaries of adjacent ones of a plurality of devices serving as recesses on a front surface side of a substrate, and the protective member is ground so that the front surface side of the protective member is planarized. This makes it possible to eliminate a gap between the substrate and the protective member or to reduce this gap in size, while making it possible to eliminate a gap between a chuck table holding the substrate through the protective member and the protective member or reduce this gap in size. Hence, by carrying out these steps prior to grinding of the back surface side of the substrate, it is possible to prevent the back surface side of the substrate from becoming uneven, in association with grinding of the back surface side of the substrate.

### BACKGROUND OF THE INVENTION

### Field of the Invention

The present invention relates to a workpiece processing method for a workpiece including a substrate whose front surface is in an uneven shape with recesses and projections attributable to formation of a plurality of devices on the front surface side of the substrate, and a protective member which adheres to each of the plurality of devices serving as the projections on the front surface side of the substrate.

### Description of the Related Art

Chips of such devices as integrated circuits (ICs) are indispensable constituent elements of various electronic apparatuses such as mobile phones and personal computers. Such chips are manufactured, for example, in the following order.

First, photolithography or the like is carried out on a substrate such as a wafer, to form a plurality of devices each including a large number of elements on a front surface side of the substrate. Next, a back surface side of the substrate is ground to reduce a thickness of the substrate. Then, the substrate is cut along boundaries of the plurality of devices to be divided into a plurality of chips.

As a method of thinning a substrate, for example, grinding of a back surface side of a substrate in a grinding apparatus is exemplified (see, for example, Japanese Patent Laid-Open No. 2014-124690). This grinding apparatus includes, in general, a chuck table for holding a front surface side of the substrate, and a spindle which has a distal end portion to which a grinding wheel having a plurality of grindstones arranged thereon in a state of being dispersed in an annular pattern is mounted.

Also, when the back surface side of the substrate is ground by this grinding apparatus, the chuck table and the spindle are individually rotated around each axis, while liquid (grinding water) is supplied to an interface between the substrate and the grinding wheel, and the chuck table and the grinding wheel are brought closer to each other in such a manner that the plurality of grindstones are brought into contact with the back surface of the substrate. Accordingly, the back surface side of the substrate is ground in a state in which the substrate is pressed by the plurality of grindstones.

### SUMMARY OF THE INVENTION

When the back surface side of the substrate is ground, a plurality of devices formed on the front surface side of the substrate are pressed, causing breakage of the devices. In view of this problem, in general, grinding of the back surface side of the substrate is carried out after a protective film is attached to the front surface side of the substrate in a state in which the substrate is held on the chuck table with this protective member interposed therebetween.

It is to be noted that the front surface side of this substrate is in an uneven shape. Specifically, when a plurality of devices are formed on the front surface side of the substrate, a region in which each of the plurality of devices is formed becomes a projection, while a region in which the plurality of devices are not formed, that is, a boundary of adjacent ones of the plurality of devices, becomes a recess. As a result, even if the protective member is attached to the front surface side of the substrate, the protective member is not attached to the region serving as each of the boundaries of adjacent ones of the plurality of devices, thereby generating a gap between the substrate and the protective member.

Then, when the back surface side of the substrate is ground in this state, the substrate pressed by the plurality of grindstones may be deformed in such a way as to sink into the relevant gap. Moreover, when the back surface side of the substrate is ground with the substrate being deformed in this manner, the regions serving as the boundaries of adjacent ones of the plurality of devices of the substrate cannot be sufficiently ground. As a result, in this case, the back surface side of the substrate after being ground may have an uneven shape.

Meanwhile, the protective member becomes soft by heating, and by attaching the softened protective member to the front surface side of the substrate, or the like, it is possible to eliminate the gap between the regions serving as the boundaries of adjacent ones of the plurality of devices and the protective member, or to make this gap smaller. In this case, however, the front surface side of the protective member, that is, a side which is not attached to the substrate, may have such an uneven shape as to reflect the uneven shape formed on the front surface side of the substrate.

Specifically, when the protective member is attached to the front surface side of the substrate in this manner, regions on the front surface side of the protective member attached to the regions in which the plurality of devices are formed become projections, and regions on the front surface side of the protective member attached to the boundaries of adjacent ones of the plurality of devices become recesses. Hence, even if the substrate with this protective member attached thereto is disposed on the chuck table, a gap may occur between the protective member and the chuck table.

Then, when the back surface side of the substrate is ground in this state, the substrate pressed by the plurality of grindstones and the protective member may be deformed in such a way as to sink into the relevant gap between the protective member and the chuck table. Moreover, when the back surface side of the substrate is thus ground in a state in which the substrate and the protective member are deformed, the regions serving as the boundaries of adjacent ones of the plurality of devices in the substrate may not sufficiently be ground. As a result, in this case, the back surface side of the substrate after being subjected to grinding may become uneven.

In view of these problems, an object of the present invention is to provide a workpiece processing method for a workpiece including a substrate and a protective member attached to the front surface side of the substrate, the processing method capable of preventing the back surface side of the substrate from becoming uneven, in association with grinding of the back surface side of the substrate.

In accordance with an aspect of the present invention, there is provided a workpiece processing method for a workpiece including a substrate whose front surface is in an uneven shape with recesses and projections attributable to formation of a plurality of devices on the front surface side of the substrate, and a protective member which adheres to each of the plurality of devices serving as the projections on the front surface side of the substrate. The workpiece processing method includes a holding step of holding a back surface side of the substrate on a chuck table, an embedding step of, after the holding step, bringing a rotating first grinding wheel closer to the chuck table, while rotating the chuck table, such that the protective member is pressed and embedded in boundaries of adjacent ones of the plurality of devices serving as the recesses on the front surface side of the substrate, and a planarization step of, after the embedding step, bringing a rotating second grinding wheel closer to the chuck table, while rotating the chuck table, such that the protective member is ground and the front surface side of the protective member is planarized.

Moreover, the workpiece processing method may preferably further include a grinding step of, after the planarization step, grinding the back surface side of the substrate.

Also, preferably, in the embedding step, liquid having a flow rate lower than a flow rate of liquid supplied to a contact interface between the protective member and the second grinding wheel in the planarization step may be supplied to a contact interface between the protective member and the first grinding wheel.

In addition, preferably, in the embedding step, liquid having a temperature higher than liquid supplied to a contact interface between the protective member and the second grinding wheel in the planarization step may be supplied to a contact interface between the protective member and the first grinding wheel.

Moreover, the first grinding wheel may preferably include grindstones having a lower concentration than that of grindstones included in the second grinding wheel. Further, the first grinding wheel may preferably include grindstones each having an edge width smaller than that of each of grindstones included in the second grinding wheel. Alternatively, the first grinding wheel and the second grinding wheel may preferably be the same grinding wheel.

In accordance with another aspect of the present invention, there is provided a workpiece processing method for a workpiece including a substrate whose front surface is in an uneven shape with recesses and projections attributable to formation of a plurality of devices on the front surface side of the substrate, and a protective member which adheres to each of the plurality of devices serving as the projections on the front surface side of the substrate. The workpiece processing method includes a holding step of holding a back surface side of the substrate on a chuck table, and an embedding planarization step of, after the holding step, bringing a rotating grinding wheel closer to the chuck table, while rotating the chuck table, such that the protective member is pressed and ground to embed the protective member in boundaries of adjacent ones of the plurality of devices serving as the recesses on the front surface side of the substrate and to planarize the front surface side of the protective member.

According to the present invention, pressing the protective member causes the protective member to be embedded in the boundaries of adjacent ones of the plurality of devices serving as the recesses on the front surface side of the substrate, and the protective member is ground so that the front surface side of the protective member is planarized.

This makes it possible to eliminate the gap between the substrate and the protective member or to reduce this gap in size and to eliminate the gap between the chuck table holding the substrate through the protective member and the protective member or to reduce this gap in size. Accordingly, by carrying out the present invention prior to grinding of the back surface side of the substrate, it is possible to prevent the back surface side of the substrate from becoming uneven, in association with grinding of the back surface side of the substrate.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1A is a perspective view schematically illustrating an example of a substrate;

FIG. 1B is a cross-sectional view schematically illustrating the substrate of FIG. 1A;

FIG. 2A is a cross-sectional view schematically illustrating how a protective member is attached to a front surface side of the substrate;

FIG. 2B is a cross-sectional view schematically illustrating an example of a workpiece including a substrate and a protective member attached to the front surface side of the substrate;

FIG. 3 is a perspective view schematically illustrating an example of a grinding apparatus;

FIG. 4 is a view schematically illustrating a chuck table and constituent elements capable of communicating with the chuck table, which are included in the grinding apparatus of FIG. 3;

FIG. 5 is a cross-sectional partial side view schematically illustrating a grinding wheel and the like included in the grinding apparatus of FIG. 3;

FIG. 6 is a flow chart schematically illustrating a workpiece processing method for grinding a workpiece in the grinding apparatus of FIG. 3;

FIG. 7 is a view schematically illustrating how a holding step S1 indicated in FIG. 6 is carried out;

FIG. 8 is a view schematically illustrating how an embedding step S2 indicated in FIG. 6 is carried out;

FIG. 9 is a cross-sectional view schematically illustrating the workpiece obtained after the embedding step S2 indicated in FIG. 6;

FIG. 10 is a view schematically illustrating how a planarization step S3 indicated in FIG. 6 is carried out;

FIG. 11 is a cross-sectional view schematically illustrating the workpiece obtained after the planarization step S3 indicted in FIG. 6;

FIG. 12 is a view schematically illustrating how an inverting step S4 indicated in FIG. 6 is carried out;

FIG. 13 is a view schematically illustrating how a grinding step S5 indicated in FIG. 6 is carried out; and

FIG. 14 is a cross-sectional view schematically illustrating the workpiece obtained after the grinding step S5 indicated in FIG. 6.

### DETAILED DESCRIPTION OF THE PREFERRED EMBODIMENT

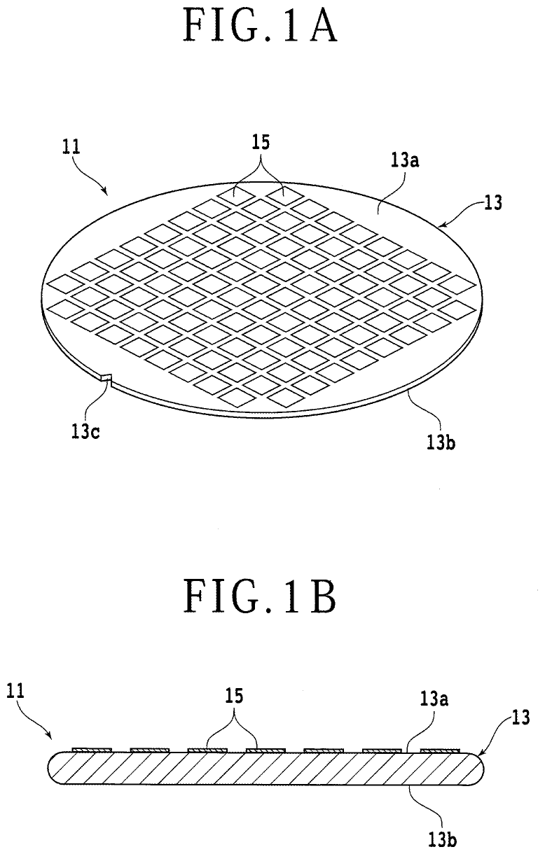

A preferred embodiment of the present invention will be described with reference to the attached drawings. FIG. 1A is a perspective view schematically illustrating an example of a substrate, and FIG. 1B is a cross-sectional view schematically illustrating the substrate of FIG. 1A.

A substrate 11 illustrated in FIG. 1A and FIG. 1B includes a circular disc-shaped wafer 13 having a front surface 13a and a back surface 13b which are substantially parallel to each other, the circular disc-shaped wafer 13 being formed of a semiconductor material such as silicon. The wafer 13 has a notch 13c formed on a side surface thereof, the notch 13c being used for indicating a specific crystal orientation of the semiconductor material constituting the wafer 13.

In addition, the wafer 13 has a plurality of devices 15 formed on the front surface 13a thereof (on a front surface side of the substrate 11). Also, the plurality of devices 15 are disposed in a matrix. Specifically, boundaries of adjacent ones of the plurality of devices 15 are present extending in a grid manner. Note that each of a plurality of linear portions included in these boundaries is referred to as a scheduled division line.

In addition, the front surface side of the substrate 11 is in an uneven shape. Specifically, of the front surface side of the substrate 11, a region in which each of the plurality of devices 15 is formed becomes a projection, while a region in which the plurality of devices 15 are not formed, that is, each boundary of adjacent ones of the plurality of devices 15 which is present extending in a grid manner becomes a recess.

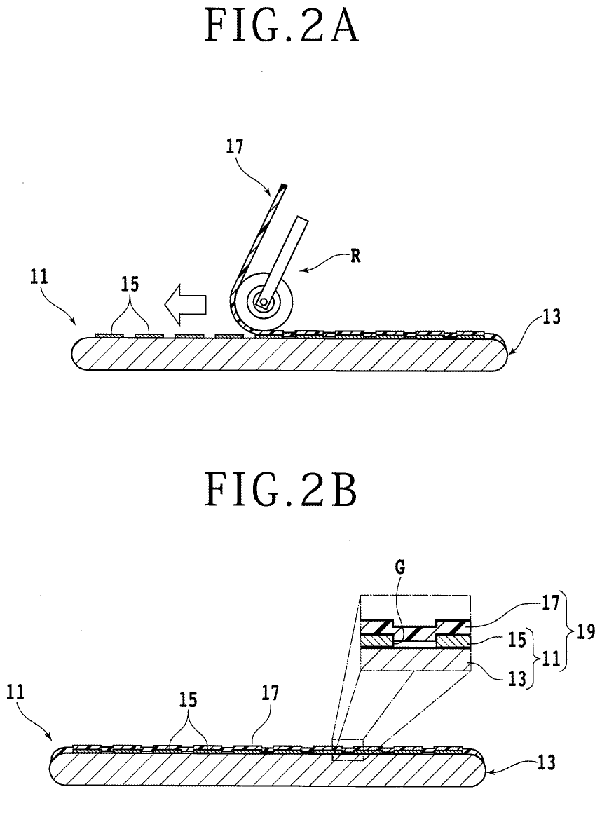

Then, a circular disc-shaped protective member having a diameter substantially equal to a diameter of the wafer 13 is attached to the front surface side of the substrate 11, prior to grinding of the back surface side thereof. FIG. 2A is a cross-sectional partial side view schematically illustrating how the protective member is attached to the front surface side of the substrate 11.

A protective member 17 to be attached to the front surface side of the substrate 11 has, for example, a film-like base sheet, and an adhesive layer (glue layer) provided on the substrate 11 side of the base sheet. Also, this base sheet is formed of, for example, resin such as polyolefin, polyvinyl chloride, or polyethylene terephthalate. Moreover, this adhesive layer is formed of, for example, an epoxy adhesive or an acrylic adhesive.

Also, the protective member 17 is pressed in such a state that the adhesive layer side of the protective member 17 is in contact with the substrate 11 by use of, for example, a pressing roller R or the like, and the protective member 17 is thereby attached to the front surface side of the substrate 11. As a result, a workpiece 19 including the substrate 11 and the protective member 17 attached to the front surface side of the substrate 11 is formed. FIG. 2B is a cross-sectional view schematically illustrating a workpiece 19 formed in this manner.

As for the workpiece 19 illustrated in FIG. 2B, while the protective member 17 is attached to each of the plurality of devices 15 serving as a projection on the front surface side of the substrate 11, the protective member 17 is not attached to each boundary of adjacent ones of the plurality of devices 15 serving as a recess. Consequently, a gap G occurs between the substrate 11 and the protective member 17.

In addition, in the workpiece 19, the protective member 17 is deformed in such a manner as to sink slightly into a portion between a pair of neighboring devices 15. Hence, the front surface side of the protective member 17, that is, a side on which the protective member 17 is not attached to the substrate 11 has such an uneven shape as to reflect the uneven shape of the front surface side of the substrate 11 to a small extent.

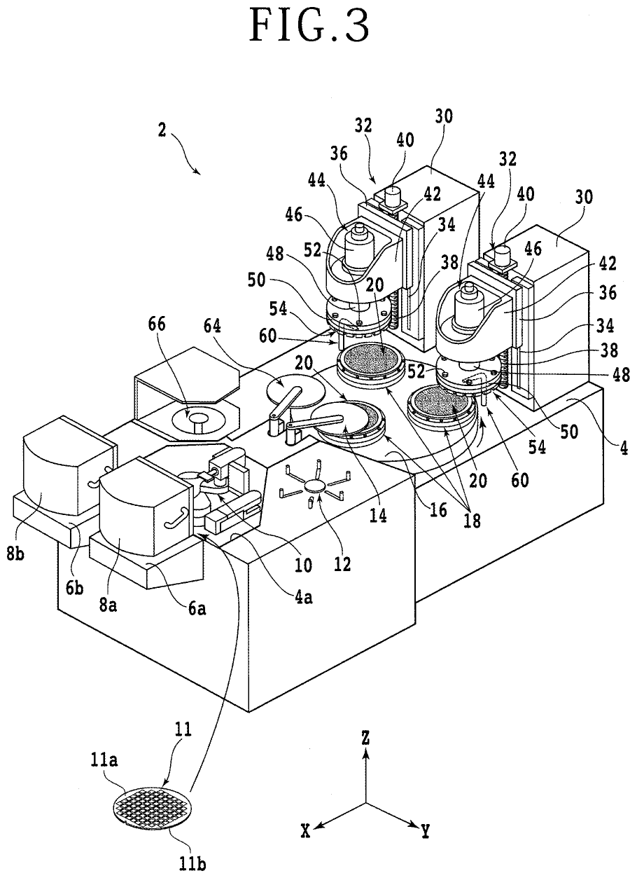

FIG. 3 is a perspective view schematically illustrating an example of a grinding apparatus for grinding the workpiece 19. Note that an X-axis direction (front-rear direction) and a Y-axis direction (left-right direction) indicated in FIG. 3 are directions perpendicular to each other on a horizontal plane, and a Z-axis direction (up-down direction) is a direction (vertical direction) perpendicular to each of the X-axis direction and the Y-axis direction.

A grinding apparatus 2 illustrated in FIG. 3 includes a base 4 which supports various types of constituent elements. On a front end surface of the base 4, there are provided cassette tables 6a and 6b. Also, the cassette tables 6a and 6b have cassettes 8a and 8b placed thereon, respectively, and each of the cassettes 8a and 8b can store a plurality of workpieces 19.

In addition, on an upper surface of the base 4 which is located slightly behind the cassette tables 6a and 6b, a depressed area 4a is formed. Inside this depressed area 4a, there is accommodated a transport mechanism 10 capable of unloading the workpiece 19 from each of the cassettes 8a and 8b or loading the workpiece 19 to each of the cassettes 8a and 8b.

This transport mechanism 10 has, for example, a plurality of joints and a robotic hand, and holds the workpiece 19 on one surface of this robotic hand. Moreover, the transport mechanism 10 is capable of inverting the robotic hand which holds the workpiece 19, that is, inverting the workpiece 19 upside down.

Moreover, obliquely behind the depressed area 4a, a position adjusting mechanism 12 for adjusting a position of the workpiece 19 is provided. The position adjusting mechanism 12 includes a circular disc-shaped position adjustment table, and a plurality of pins disposed around the position adjustment table. Then, the transport mechanism 10 causes the workpiece 19 unloaded from the cassette 8a or 8b to be loaded onto this position adjustment table such that a center of the workpiece 19 is adjusted to a predetermined position.

More specifically, when the workpiece 19 is loaded onto the position adjustment table, the plurality of pins approach the position adjustment table along a radial direction of the position adjustment table. As such, the plurality of pins come into contact with a side surface of the workpiece 19 to thereby move the workpiece 19 to a small extent. As a result, the center of the workpiece 19 is aligned with the predetermined position.

In addition, on a lateral side of the position adjusting mechanism 12, another transport mechanism 14 which transports the workpiece 19 therebehind in such a manner as to hold the workpiece 19 is provided. The transport mechanism 14 has, for example, a support shaft extending in the Z-axis direction, an arm which has a proximal end portion fixed to an upper end portion of this support shaft and extends in a direction perpendicular to the Z-axis direction, and a suction pad which is fixed to a lower side of a distal end portion of this arm.

In addition, the support shaft of the transport mechanism 14 is connected to a rotary mechanism (not illustrated) such as a motor. When this rotary mechanism is operated, with a straight line parallel to the Z-axis direction as a rotary axis, the support shaft is rotated about the rotary axis. In addition, the support shaft of the transport mechanism 14 is coupled with a moving mechanism (not illustrated) such as an air cylinder. When this moving mechanism is operated, the support shaft is moved along the Z-axis direction, that is, the support shaft is moved vertically.

For example, the transport mechanism 14 holds the workpiece 19 to transport it therebehind, in the following order. First, the rotary mechanism rotates the support shaft such that the suction pad of the transport mechanism 14 is positioned immediately above the workpiece 19 whose center is aligned with the predetermined position in the position adjusting mechanism 12. Next, the moving mechanism moves the support shaft downward such that this suction pad comes into contact with the workpiece 19.

Next, the suction pad sucks the upper surface side of the workpiece 19 such that the workpiece 19 is held on the suction pad. Then, in such a manner as to raise the suction pad holding the workpiece 19, the moving mechanism moves the support shaft upward. Subsequently, the rotary mechanism rotates the support shaft such that the suction pad holding the workpiece 19 turns. Hence, the workpiece 19 is transported behind the transport mechanism 14.

Behind the transport mechanism 14, a turntable 16 is provided. The turntable 16 is connected to a rotary mechanism such as a motor (not illustrated). When this rotary mechanism is operated, with a straight line passing through a center of an upper surface of the turntable 16 and parallel to the Z-axis direction as a rotary axis, for example, the turntable 16 is rotated along a direction of an arrow illustrated in FIG. 3.

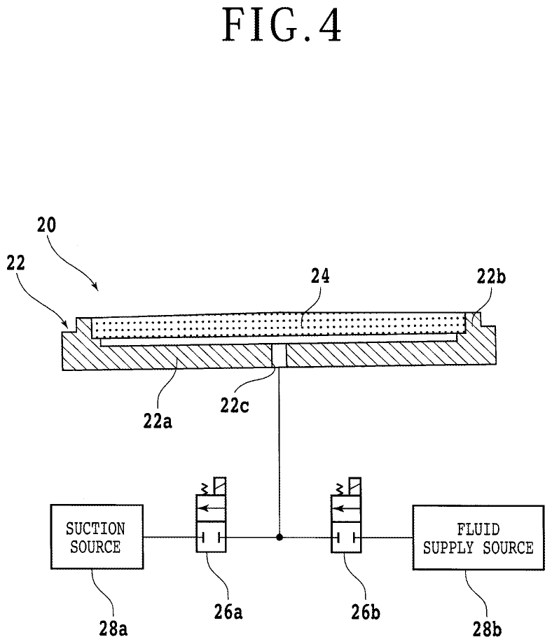

Also, the turntable 16 has three circular disc-shaped table bases 18 provided thereon at a substantially equal angular interval along a circumferential direction of the turntable 16. In addition, on an upper end portion of each of the table bases 18, a chuck table 20 for holding the workpiece 19 is mounted. FIG. 4 is a view schematically illustrating the chuck table 20 and constituent elements capable of communicating with the chuck table 20.

The chuck table 20 has a circular disc-shaped frame body 22 formed of, for example, ceramic or the like. The frame body 22 has a circular disc-shaped bottom wall 22a, and a cylindrical side wall 22b erected from an outer peripheral portion of the bottom wall 22a. Specifically, on an upper surface side of the frame body 22, a circular disc-shaped recess portion defined by the bottom wall 22a and the side wall 22b is formed. Also, a circular disc-shaped porous plate 24 formed of porous ceramic or the like is fixed to this recess portion.

Note that an upper surface of the side wall 22b of the frame body 22 and an upper surface of the porous plate 24 have a shape corresponding to a side surface of a cone, functioning as a holding surface for holding the workpiece 19. Besides, the bottom wall 22a is formed with a flow channel 22c which is opened at a bottom surface of the recess portion and penetrates the bottom wall 22a. In addition, the flow channel 22c is connected to a suction source 28a through a valve 26a and connected to a fluid supply source 28b through a valve 26b.

The suction source 28a includes, for example, an ejector or the like. Also, the fluid supply source 28b includes, for example, a tank for storing high-pressure air, a filter for removing foreign matter which is mixed into the air supplied from the tank, and a regulator for regulating pressure of the air supplied from the tank.

Moreover, the chuck table 20 is connected to a rotary mechanism (not illustrated). This rotary mechanism includes, for example, a motor, a pulley, and the like. When the rotary mechanism is operated, with a straight line passing through a center of the holding surface of the chuck table 20 as its rotary axis, the chuck table 20 is rotated around the rotary axis.

Besides, the chuck table 20 is supported by an inclination adjusting mechanism (not illustrated) through the table base 18. This inclination adjusting mechanism includes one fixed shaft and two movable shafts which are disposed along the circumferential direction of the chuck table 20 at a substantially equal angular interval. Also, when at least one of the two movable shafts partially moves the table base 18 and the chuck table 20 upward, inclination of the rotary axis of the chuck table 20 is adjusted.

Note that the turntable 16 is rotated along the direction of the arrow illustrated in FIG. 3 in a state in which the chuck table 20 is mounted on the table base 18, the chuck table 20 moves together with the table base 18. Accordingly, the table base 18 and the chuck table 20 can be positioned in order, for example, at a loading/unloading position next to the transport mechanism 14, at a first grinding position obliquely behind the loading/unloading position, and a second grinding position on a lateral side of the first grinding position.

Then, the workpiece 19 transported by the transport mechanism 14 therebehind is loaded on the chuck table 20 positioned at the loading/unloading position. Loading of the workpiece 19 onto the chuck table 20 is carried out, for example, in the following order.

First, in such a manner that the workpiece 19 held by the suction pad of the transport mechanism 14 approaches the holding surface of the chuck table 20, the moving mechanism coupled with the support shaft of the transport mechanism 14 lowers the support shaft. Next, suction of the upper surface of the workpiece 19 by the suction pad is stopped. As a result, the workpiece 19 is separated from the suction pad and loaded onto the chuck table 20.

Then, when the workpiece 19 is loaded onto the chuck table 20, the suction source 28a is operated with the valve 26a being opened such that the lower surface side of the workpiece 19 is sucked and held by the chuck table 20. Next, the turntable 16 is rotated such that the chuck table 20 holding the workpiece 19 is positioned at the first grinding position or the second grinding position.

Behind each of the first grinding position and the second grinding position, a columnar shaped support structure 30 is provided. Then, on a front face side of each of the support structures 30, a moving mechanism 32 is provided. Each moving mechanism 32 includes a pair of guide rails 34 extending along the Z-axis direction. Moreover, the pair of guide rails 34 has a moving plate 36 slidably attached thereon.

Also, a nut (not illustrated) is fixed on a rear face side (a back surface side) of the moving plate 36, the nut being included in a ball screw, and this nut is coupled with a screw shaft 38 extending along the Z-axis direction in a rotatable manner. Moreover, a motor 40 is connected to one end (upper end portion) of the screw shaft 38. Also, when the screw shaft 38 is rotated by the motor 40, the moving plate 36 is moved together with the nut along the Z-axis direction.

Moreover, a fixture 42 is provided on a front face (a front surface) of the moving plate 36. Also, the fixture 42 supports a grinding unit 44. The grinding unit 44 has a spindle housing 46 which is fixed to the fixture 42. Moreover, the spindle housing 46 houses a spindle 48 extending in the Z-axis direction or a direction being slightly inclined to the Z-axis direction in a rotatable manner.

Further, a lower end portion (distal end portion) of the spindle 48 is exposed from the spindle housing 46, serving as a circular plate-shaped mount 50. In addition, on an outer edge portion of the mount 50, there are provided a plurality of through-holes (not illustrated) penetrating the mount 50 in a thickness direction of the mount 50, and a bolt 52 is inserted into each of the through-holes.

Also, a grinding wheel 54 for rough grinding, for example, is mounted on a lower surface of the mount 50 of the grinding unit 44 on the first grinding position side, by use of the bolt 52. Similarly, a grinding wheel 54 for finish grinding, for example, is mounted on a lower surface of the mount 50 of the grinding unit 44 on the second grinding position side, by use of the bolt 52.

Alternatively, a grinding wheel (the first grinding wheel) 54 to be used in an embedding step S2 described later may be mounted on the lower surface of the mount 50 of the grinding unit 44 on one of the first grinding position side or the second grinding position side, and, a grinding wheel (the second grinding wheel) 54 to be used in a planarization step S3 described later may be mounted on the lower surface of the mount 50 of the grinding unit 44 on the other of the first grinding position side or the second grinding position side.

Also, the spindle housing 46 houses a rotary mechanism such as a motor connected to a proximal end portion (upper end portion) of the spindle 48. In addition, when the rotary mechanism is operated, the grinding wheel 54 is rotated together with the spindle 48 with a straight line extending along the Z-axis direction or a direction being slightly inclined to the Z-axis direction as its rotary axis.

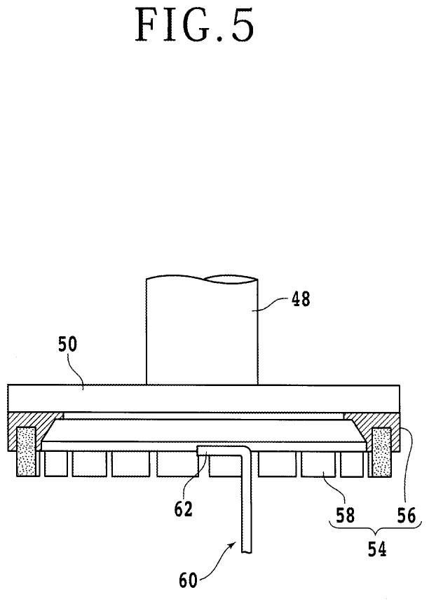

FIG. 5 is a cross-sectional partial side view schematically illustrating the grinding wheel 54 and the like included in the grinding apparatus 2 of FIG. 3. The grinding wheel 54 includes an annular wheel base 56 formed of metal such as stainless steel or aluminum. Also, a plurality of grindstones 58 are fixed on a lower surface of the wheel base 56 along its circumferential direction at a substantially equal angular interval. In addition, each of the plurality of grindstones 58 includes a binder such as a vitrified bond or a resinoid bond, and abrasive grains, such as diamond, being dispersed in this binder.

Moreover, in the vicinity of the grinding wheel 54, a liquid supply unit 60 is provided. The liquid supply unit 60 includes, for example, a nozzle 62 which is positioned inside the grinding wheel 54 in plan view, and a pump (not illustrated) which supplies the nozzle 62 with liquid such as deionized water.

Then, when this pump is operated, liquid is supplied from the nozzle 62 to the workpiece 19 held on the chuck table 20 that is positioned at the first grinding position or the second grinding position. Also, in the liquid supply unit 60, in place of the nozzle 62, or in addition to the nozzle 62, liquid may be supplied through the flow channel formed in the grinding wheel 54.

Also, when the chuck table 20 holding the workpiece 19 is positioned at the first grinding position or the second grinding position, grinding of the upper surface side of the workpiece 19 is carried out. Note that an example of grinding on the upper surface side of the workpiece 19 will be described later. Then, when this grinding is completed, in such a manner that the chuck table 20 holding the workpiece 19 is positioned at the loading/unloading position, the turntable 16 is further rotated along the direction of the arrow indicated in FIG. 3.

In front of the loading/unloading position and the lateral side of the transport mechanism 14, there is provided another transport mechanism 64 which holds and transports the workpiece 19 forward. The transport mechanism 64 has a structure similar to that of the transport mechanism 14, for example.

Also, the transport mechanism 64 transports the ground workpiece 19 held on the chuck table 20 that is positioned at the loading/unloading position, for example. For example, unloading of the workpiece 19 from the chuck table 20 is carried out in the following order.

First, in such a manner that the workpiece 19 is separated from the chuck table 20, operation of the suction source 28a is stopped with the valve 26a being closed, and the fluid supply source 28b is operated with the valve 26b being opened. Subsequently, in such a manner that the suction pad of the transport mechanism 64 is made closer to the workpiece 19 held on the chuck table 20, the moving mechanism coupled with the support shaft of the transport mechanism 64 lowers the support shaft.

Next, the suction pad sucks the upper surface side of the workpiece 19 such that the workpiece 19 is held by the suction pad. Then, the moving mechanism moves the support shaft upward in such a manner as to move upward the suction pad holding the workpiece 19. Subsequently, the rotary mechanism rotates the support shaft so as to turn the suction pad holding the workpiece 19. Hence, the workpiece 19 is transported forward.

Then, the ground workpiece 19 unloaded from the chuck table 20 is loaded to a cleaning unit 66 provided on a lateral side of the transport mechanism 64. The cleaning unit 66 includes, for example, a spinner table rotating in a state of holding the lower surface side of the workpiece 19, and a cleaning nozzle supplying the upper surface side of the workpiece 19 held on the spinner table with a cleaning fluid.

Note that the cleaning fluid to be used in the cleaning unit 66 is, for example, a fluid into which water and air are mixed. Alternatively, this cleaning fluid may contain only liquid such as water. Then, when cleaning of the upper surface side of the workpiece 19 in the cleaning unit 66 is completed, the transport mechanism 10 transports the workpiece 19 from the cleaning unit 66 to the cassette 8a or 8b.

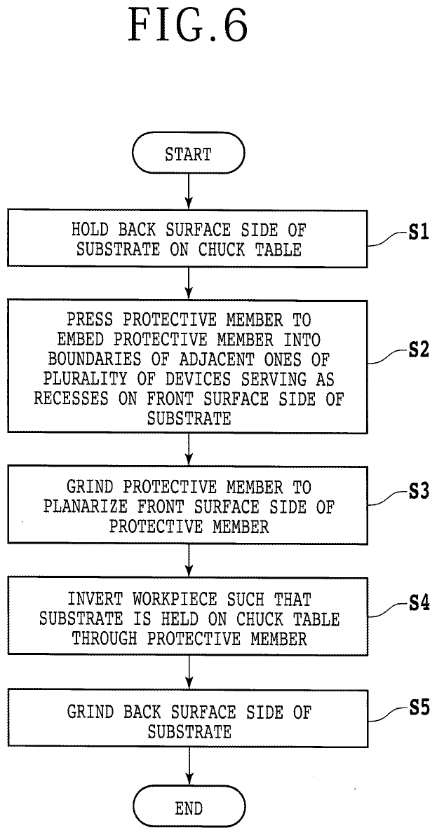

FIG. 6 is a flow chart schematically illustrating a workpiece processing method for processing the workpiece 19 in the grinding apparatus 2. To put it simply, this method is an example of a method of embedding the protective member 17 in the boundaries of adjacent ones of the plurality of devices 15 serving as the recesses on the front surface side of the substrate 11 of the workpiece 19, and planarizing the front surface side of the protective member 17 to grind the back surface side of the substrate 11.

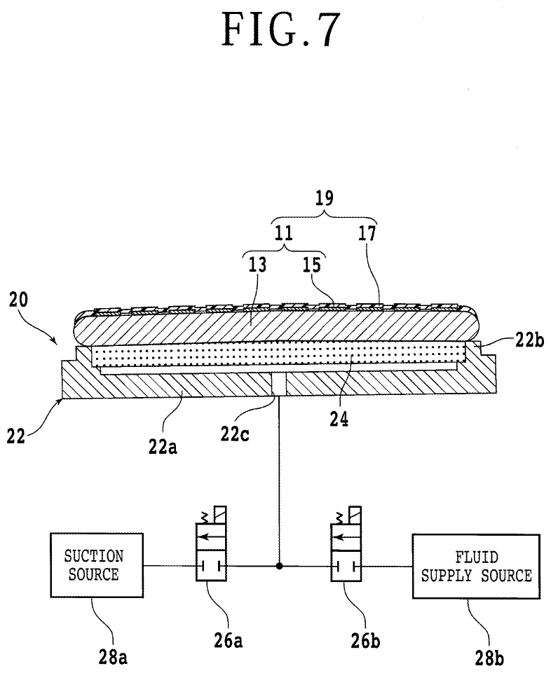

Specifically, in this method, first, the back surface side of the substrate 11, that is, the side on which the plurality of devices 15 are not formed, is held on the chuck table 20 (holding step S1). FIG. 7 is a view schematically illustrating how the holding step S1 is carried out.

In this holding step S1, first, with use of the transport mechanisms 10 and 14 and the like, the workpiece 19 unloaded from the cassette 8a or 8b is loaded onto the chuck table 20 in such a manner that the protective member 17 attached to the workpiece 19 is oriented upward. Then, the suction source 28a is operated, and the valve 26a is made to be opened. As such, the back surface side of the substrate 11 is held on the chuck table 20.

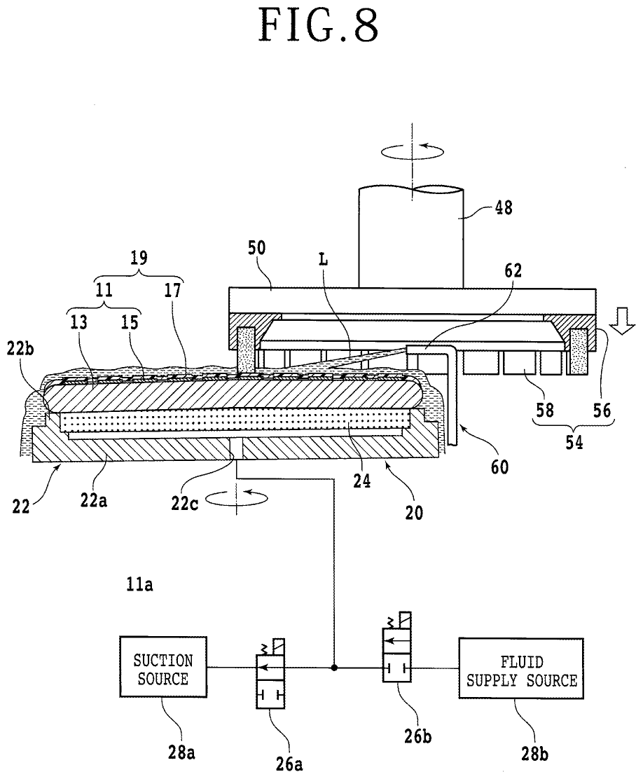

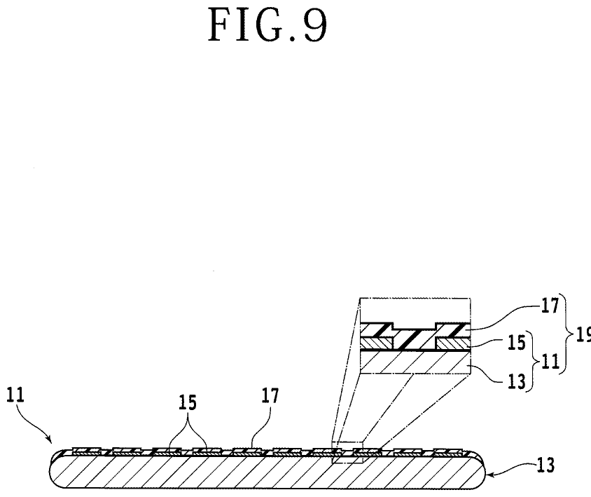

After the holding step S1, the protective member 17 is first pressed, and the protective member 17 is embedded in the boundaries of adjacent ones of the plurality of devices 15 serving as the recesses on the front surface side of the substrate 11 (embedding step S2). FIG. 8 is a view schematically illustrating how the embedding step S2 is carried out. FIG. 9 is a cross-sectional view schematically illustrating the workpiece 19 after the embedding step S2.

In this embedding step S2, first, the grinding wheel 54 to be used in the embedding step S2 is mounted to the lower surface of the mount 50 of the grinding unit 44 on one of the first grinding position side or the second grinding position side, with use of the bolt 52. Note that this mounting of the grinding wheel 54 may be carried out prior to the holding step S1.

Also, in the embedding step S2, such that the protective member 17 can be locally pressed, the grinding wheel 54 including the grindstones 58 having small edge widths, that is, small lengths along a radial direction of the grinding wheel 54, may preferably be used. For example, the edge widths of the grindstones 58 included in the grinding wheel 54 to be used in the embedding step S2 may preferably be smaller than 3.0 mm.

Also, in the embedding step S2, in such a manner that the protective member 17 is not excessively ground, the grinding wheel 54 including the grindstones 58 having a small concentration, that is, the grindstones 58 having a small volume ratio of the abrasive grains contained in the grindstones 58, may preferably be used. For example, the concentration of the grindstones 58 included in the grinding wheel 54 to be used in the embedding step S2 may preferably be lower than 100.

Next, in such a manner that the workpiece 19 is positioned directly below the grinding wheel 54 used in the embedding step S2, the turntable 16 is rotated to position the chuck table 20 holding the workpiece 19 at one of the first grinding position or the second grinding position. Then, both the chuck table 20 and the grinding wheel 54 are rotated about their own axes.

Next, in such a manner that the protective member 17 and the plurality of grindstones 58 are brought into contact with each other, the rotating grinding wheel 54 is brought closer to the chuck table 20 while rotating the chuck table 20. Specifically, the grinding wheel 54 is lowered while both of them are rotated. In addition, immediately before the protective member 17 and the plurality of grindstones 58 come into contact with each other, liquid L is supplied to a contact interface between the protective member 17 and the plurality of grindstones 58 from the nozzle 62.

Note that, in the embedding step S2, such that the protective member 17 is easily softened, the liquid L having a high temperature may preferably be supplied to the contact interface between the protective member 17 and the plurality of grindstones 58. For example, in the embedding step S2, the temperature of the liquid L supplied to the contact interface between the protective member 17 and the plurality of grindstones 58 may preferably be equal to or larger than 25° C.

Also, in the embedding step S2, to prevent the protective member 17 softened by frictional heat from being excessively cooled by the liquid L, it is preferred that the liquid L having a low flow rate be supplied to the contact interface between the protective member 17 and plurality of grindstones 58. For example, in the embedding step S2, the flow rate of liquid L supplied to the contact interface between the protective member 17 and the plurality of grindstones 58 may preferably be lower than 2.0 L/min.

Also, in the embedding step S2, in a state in which the liquid L is supplied to the contact interface between the protective member 17 and the plurality of grindstones 58, the protective member 17 is pressed by the plurality of grindstones 58 (see FIG. 8). Hence, to eliminate a gap G between the substrate 11 and the protective member 17 or reduce this gap G in size, the protective member 17 is embedded in the boundaries of adjacent ones of the plurality of devices 15 serving as the recesses on the front surface side of the substrate 11 (see FIG. 9).

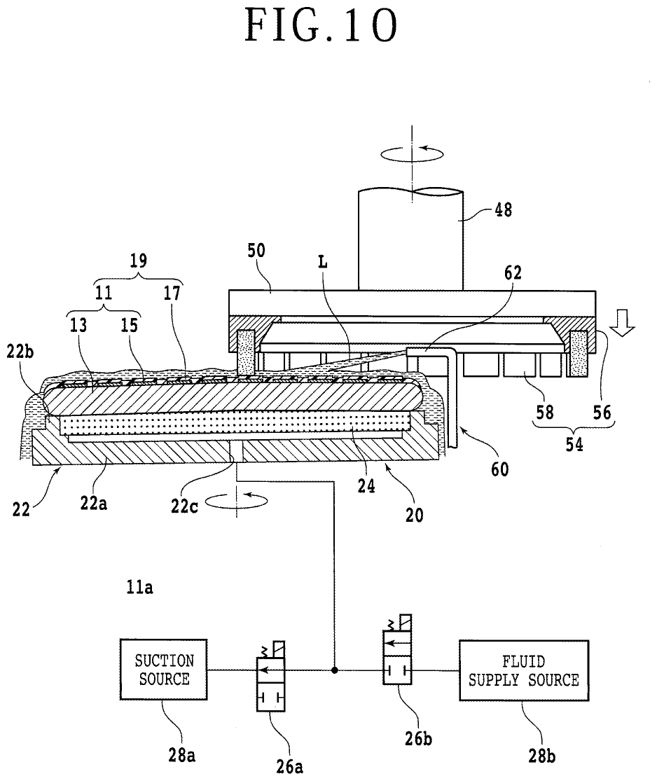

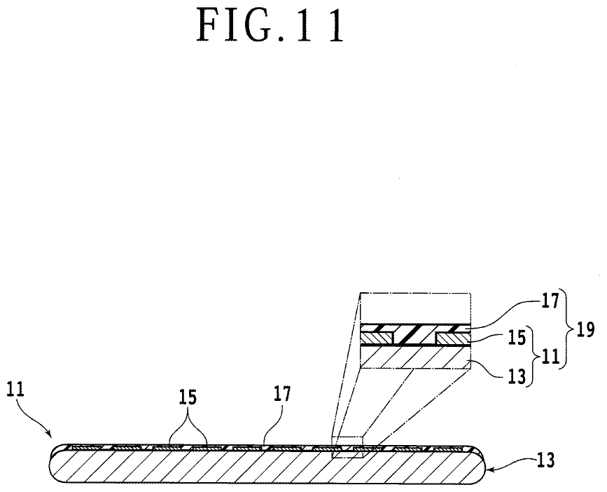

Subsequent to the embedding step S2, the protective member 17 is ground, so that the front surface side of the protective member 17 is planarized (planarization step S3). FIG. 10 is a view schematically illustrating how the planarization step S3 is carried out. FIG. 11 is a cross-sectional view schematically illustrating the workpiece 19 after the planarization step S3.

In this planarization step S3, first, rotation of both the chuck table 20 holding the workpiece 19 and the grinding wheel 54 used in the embedding step S2 is stopped, and the grinding wheel 54 is separated from the protective member 17, specifically, the grinding wheel 54 is moved upward.

Next, the grinding wheel 54 used in the embedding step S2 is replaced with that to be used in the planarization step S3. Note that, in the embedding step S2 and the planarization step S3, the same grinding wheel 54 may be used. In this case, replacement of the grinding wheel 54 becomes unnecessary.

Also, the grinding wheel 54 to be used in the planarization step S3 may be mounted in advance to the lower surface of the mount 50 of the other grinding unit 44 on the first grinding position side or the second grinding position side. In this case, without conducting replacement of the grinding wheel 54, the turntable 16 may be rotated such that the chuck table 20 holding the workpiece 19 is positioned at the other of the first grinding position or the second grinding position.

Note that, in the planarization step S3, in order to be able to uniformly grind the entire region of the front surface side of the protective member 17, it is preferable to use the grinding wheel 54 including the grindstones 58 having larger edge widths than those of the grindstones 58 included in the grinding wheel 54 used in the embedding step S2. For example, the edge widths of the grindstones 58 included in the grinding wheel 54 to be used in the planarization step S3 may preferably be equal to or larger than 3.0 mm.

In addition, in the planarization step S3, to smoothly grind the protective member 17, it is preferable to use the grinding wheel 54 including the grindstones 58 having a higher concentration than that of the grindstones 58 included in the grinding wheel 54 used in the embedding step S2. For example, the concentration of the grindstones 58 included in the grinding wheel 54 used in the planarization step S3 may preferably be equal to or higher than 100.

Next, as in the embedding step S2, the grinding apparatus 2 is operated. Specifically, in a state in which the liquid L is supplied to the contact interface between the protective member 17 and the plurality of grindstones 58, in such a manner that the protective member 17 and the plurality of grindstones 58 are brought into contact with each other, the rotating grinding wheel 54 is brought closer to the chuck table 20, while rotating the chuck table 20.

Note that, in the planarization step S3, such that the protective member 17 is less likely to be softened, the liquid L having a lower temperature than that of the liquid L used in the embedding step S2 may preferably be supplied to the contact interface between the protective member 17 and the plurality of grindstones 58. For example, in the planarization step S3, the temperature of the liquid L supplied to the contact interface between the protective member 17 and the plurality of grindstones 58 may preferably be smaller than 25° C.

In addition, in the planarization step S3, such that the protective member 17 softened by the frictional heat is sufficiently cooled by the liquid L, the flow rate of the liquid L higher than that of the liquid L used in the embedding step S2 may preferably be supplied to the contact interface between the protective member 17 and the plurality of grindstones 58. For example, in the planarization step S3, the flow rate of the liquid L supplied to the contact interface between the protective member 17 and the plurality of grindstones 58 may preferably be equal to or larger than 2.0 L/min.

Also, in the planarization step S3, in a state in which the liquid L is supplied to the contact interface between the protective member 17 and the plurality of grindstones 58, the protective member 17 is ground by the plurality of grindstones 58 (see FIG. 10). Hence, the front surface side of the protective member 17 is planarized (see FIG. 11).

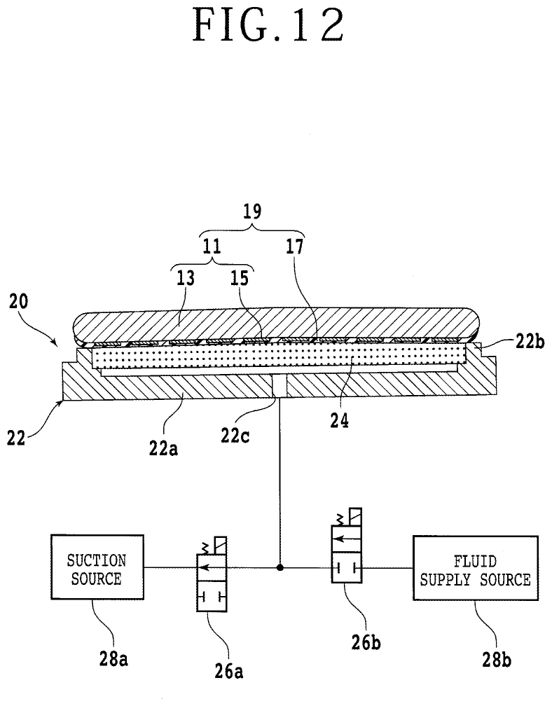

After the planarization step S3 is carried out, the workpiece 19 is inverted such that the substrate 11 is held on the chuck table 20 through the protective member 17 (inverting step S4). FIG. 12 is a view schematically illustrating how the inverting step S4 is carried out.

In this inverting step S4, first, while both rotations of the chuck table 20 holding the workpiece 19 and the grinding wheel 54 used in the planarization step S3 are stopped, the grinding wheel 54 is separated from the protective member 17, that is, the grinding wheel 54 is moved upward.

Next, such that the chuck table 20 holding the workpiece 19 is positioned at the loading/unloading position, the turntable 16 is rotated. Next, while operation of the suction source 28a is stopped, the valve 26a is put into a closed state. While the fluid supply source 28b is operated, the valve 26b is put into an opened state. Accordingly, unloading of the workpiece 19 from the chuck table 20 is enabled.

Next, by use of the transport mechanism 64, such that the protective member 17 faces upward, the workpiece 19 unloaded from the chuck table 20 is loaded to the cleaning unit 66. Then, in the cleaning unit 66, the upper surface side of the workpiece 19 is cleaned. Accordingly, grinding swarf generated in the planarization step S3, that is, dust attributable to processing on the protective member 17, is washed away from the upper surface side of the workpiece 19.

Next, by use of the transport mechanisms 10 and 14 and the like, in such a manner that the protective member 17 faces downward, the workpiece 19 unloaded from the cleaning unit 66 is again loaded to the chuck table 20. Then, the suction source 28a is operated, and the valve 26a is put into an opened state. Hence, the substrate 11 is held on the chuck table 20 through the protective member 17, that is, the front surface side of the protective member 17 is held on the chuck table 20.

Here, the front surface side of the protective member 17 is planarized in the planarization step S3. Hence, in the inverting step S4, it is possible to eliminate a gap between the chuck table 20 and the protective member 17 or to reduce this gap in size.

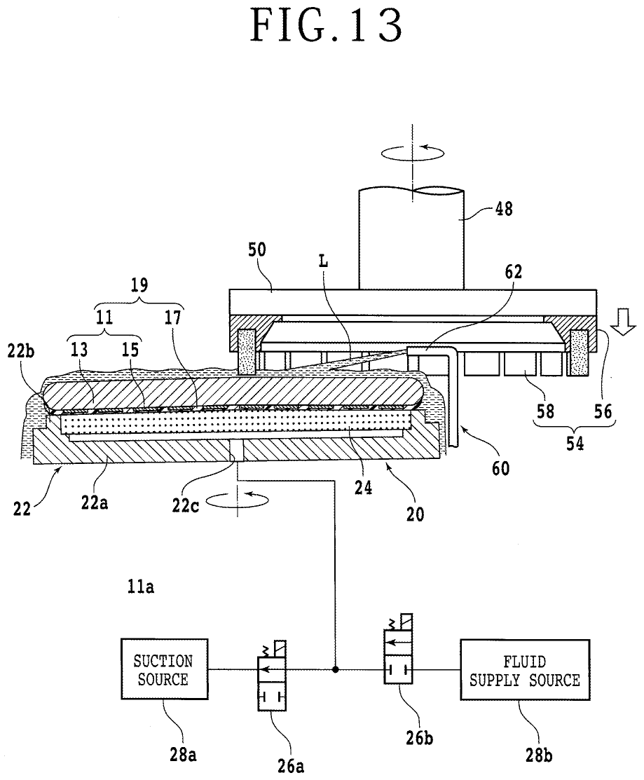

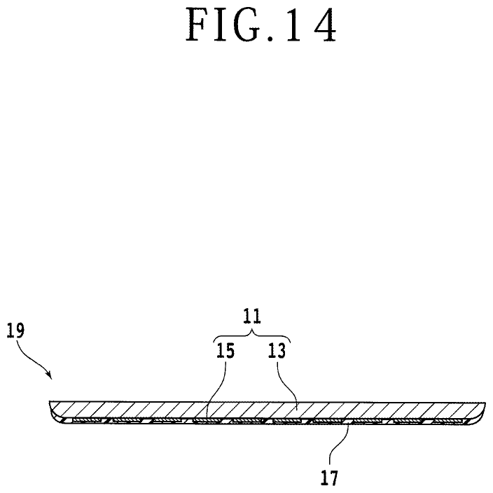

After the inverting step S4, the back surface side of the substrate 11 is ground (grinding step S5). FIG. 13 is a view schematically illustrating how the grinding step S5 is carried out. FIG. 14 is a cross-sectional view schematically illustrating the workpiece 19 after the grinding step S5.

First, in the grinding step S5, first, the grinding wheel 54 for rough grinding is mounted to the lower surface of the mount 50 of the grinding unit 44 on the first grinding position side with use of the bolt 52, and the grinding wheel 54 for finish grinding is mounted to the lower surface of the mount 50 of the grinding unit 44 on the second grinding position side with use of the bolt 52. Note that the grinding wheel 54 for rough grinding and the grinding wheel 54 for finish grinding can be mounted prior to the inverting step S4.

Also, the grinding wheel 54 for rough grinding may be the same as the grinding wheel 54 used in one of the embedding step S2 or the planarization step S3. In addition, the grinding wheel 54 for finish grinding may be the same as the grinding wheel 54 used in the other one of the embedding step S2 or the planarization step S3. In these cases, replacement of the grinding wheel 54 becomes unnecessary.

Next, such that the chuck table 20 holding the workpiece 19 is positioned at the first grinding position, the turntable 16 is rotated. Next, as in the embedding step S2 and the planarization step S3, the grinding apparatus 2 is operated.

Specifically, in a state in which the liquid L is supplied to the contact interface between the substrate 11 and the plurality of grindstones 58, in such a manner to bring the substrate 11 and the plurality of grindstones 58 into contact with each other, the rotating grinding wheel 54 for rough grinding is brought closer to the chuck table 20, while rotating the chuck table 20. Hence, the back surface side of the substrate 11 is subjected to rough grinding.

Next, while both rotations of the chuck table 20 holding the workpiece 19 and the grinding wheel 54 for rough grinding are stopped, the grinding wheel 54 is separated from the protective member 17, that is, the grinding wheel 54 is moved upward.

Next, such that the chuck table 20 holding the workpiece 19 is positioned at the second grinding position, the turntable 16 is rotated. Then, as in the embedding step S2 and the planarization step S3, the grinding apparatus 2 is operated.

More specifically, in a state in which the liquid L is supplied to the contact interface between the substrate 11 and the plurality of grindstones 58, in such a manner as to bring the substrate 11 and the plurality of grindstones 58 into contact with each other, the rotating grinding wheel 54 for finish grinding is brought closer to the chuck table 20, while rotating the chuck table 20. Hence, the back surface side of the substrate 11 is subjected to finish grinding.

As described above, grinding of the back surface side of the substrate 11 is completed. In this case, there is no gap between the chuck table 20 and the protective member 17, or this gap is small. Accordingly, in the grinding step S5, it is possible to prevent the back surface side of the substrate 11 from being an uneven shape, in association with grinding.

In the workpiece processing method indicated in FIG. 6, by pressing the protective member 17 in the embedding step S2, the protective member 17 is embedded in the boundaries of adjacent ones of the plurality of devices 15 serving as the recesses on the front surface side of the substrate 11, and in the planarization step S3, the protective member 17 is ground so that the front surface side of the protective member 17 is planarized.

This enables the gap G between the substrate 11 and the protective member 17 to be eliminated or to be reduced in size and, at the same time, enables the gap between the chuck table 20 holding the substrate 11 through the protective member 17 and the protective member 17 to be eliminated or to be reduced in size. Hence, by carrying out the embedding step S2 and the planarization step S3 prior to the grinding step S5, it is possible to prevent the back surface side of the substrate 11 from becoming uneven, in association with grinding of the back surface side of the substrate 11.

Note that the description described above is an aspect of the present invention, and the description of the present invention is not limited to the foregoing description. For example, in the present invention, the grinding apparatus which carries out the holding step S1, the embedding step S2, and the planarization step S3 may be different from the grinding apparatus which carries out the grinding step S5. Also, in the present invention, a provider who carries out the holding step S1, the embedding step S2, and the planarization step S3 may be different from a provider who carries out the grinding step S5.

Moreover, in the present invention, embedding of the protective member 17 into the boundaries of adjacent ones of the plurality of devices 15 and planarization of the front surface side of the protective member 17 may be carried out simultaneously. Specifically, the present invention may be a workpiece processing method including an embedding planarization step of, after the holding step S1, bringing the rotating grinding wheel 54 closer to the chuck table 20, while rotating the chuck table 20, in such a manner as to press and grind the protective member 17 to thereby embed the protective member 17 in the boundaries of adjacent ones of the plurality of devices 15 serving as the recesses on the front surface side of the substrate 11 and planarize the front surface side of the protective member 17, in place of the embedding step S2 and the planarization step S3.

Besides, a structure, a method, and the like according to the above embodiment may be appropriately modified, and various modifications can be implemented without departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A workpiece processing method for a workpiece including a substrate whose front surface is in an uneven shape with recesses and projections attributable to formation of a plurality of devices on the front surface side of the substrate, and a protective member which adheres to each of the plurality of devices serving as the projections on the front surface side of the substrate, the method comprising:
a holding step of holding a back surface side of the substrate on a chuck table;
an embedding step of, after the holding step, bringing a rotating first grinding wheel closer to the chuck table, while rotating the chuck table, such that the protective member is pressed and embedded in boundaries of adjacent ones of the plurality of devices serving as the recesses on the front surface side of the substrate; and
a planarization step of, after the embedding step, bringing a rotating second grinding wheel closer to the chuck table, while rotating the chuck table, such that the protective member is ground and the front surface side of the protective member is planarized.

2. The workpiece processing method according to claim 1, further comprising:
a grinding step of, after the planarization step, grinding the back surface side of the substrate.

3. The workpiece processing method according to claim 1, wherein,
in the embedding step, liquid having a flow rate lower than a flow rate of liquid supplied to a contact interface between the protective member and the second grinding wheel in the planarization step is supplied to a contact interface between the protective member and the first grinding wheel.

4. The workpiece processing method according to claim 1, wherein,
in the embedding step, liquid having a temperature higher than liquid supplied to a contact interface between the protective member and the second grinding wheel in the planarization step is supplied to a contact interface between the protective member and the first grinding wheel.

5. The workpiece processing method according to claim 1, wherein
the first grinding wheel includes grindstones having a lower concentration than that of grindstones included in the second grinding wheel.

6. The workpiece processing method according to claim 1, wherein
the first grinding wheel includes grindstones each having an edge width smaller than that of each of grindstones included in the second grinding wheel.

7. The workpiece processing method according to claim 1, wherein
the first grinding wheel and the second grinding wheel are a same grinding wheel.

8. The workpiece processing method according to claim 2, wherein,
in the embedding step, liquid having a flow rate lower than a flow rate of liquid supplied to a contact interface between the protective member and the second grinding wheel in the planarization step is supplied to a contact interface between the protective member and the first grinding wheel.

9. The workpiece processing method according to claim 2, wherein,
in the embedding step, liquid having a temperature higher than liquid supplied to a contact interface between the protective member and the second grinding wheel in the planarization step is supplied to a contact interface between the protective member and the first grinding wheel.

10. The workpiece processing method according to claim 2, wherein
the first grinding wheel includes grindstones having a concentration lower than that of grindstones included in the second grinding wheel.

11. The workpiece processing method according to claim 2, wherein
the first grinding wheel includes grindstones each having an edge width smaller than that of each of grindstones included in the second grinding wheel.

12. The workpiece processing method according to claim 2, wherein
the first grinding wheel and the second grinding wheel are a same grinding wheel.

13. The workpiece processing method according to claim 3, wherein,
in the embedding step, liquid having a temperature higher than that of the liquid supplied to the contact interface between the protective member and the second grinding wheel in the planarization step is supplied to the contact interface between the protective member and the first grinding wheel.

14. The workpiece processing method according to claim 8, wherein,
in the embedding step, liquid having a temperature higher than that of the liquid supplied to the contact interface between the protective member and the second grinding wheel in the planarization step is supplied to the contact interface between the protective member and the first grinding wheel.

15. A workpiece processing method for a workpiece including a substrate whose front surface is in an uneven shape with recesses and projections attributable to formation of a plurality of devices on the front surface side of the substrate, and a protective member which adheres to each of the plurality of devices serving as the projections on the front surface side of the substrate, the method comprising:
a holding step of holding a back surface side of the substrate on a chuck table; and
an embedding planarization step of, after the holding step, bringing a rotating grinding wheel closer to the chuck table, while rotating the chuck table, such that the protective member is pressed and ground to embed the protective member in boundaries of adjacent ones of the plurality of devices serving as the recesses on the front surface side of the substrate and to planarize the front surface side of the protective member.
